(19) United States
(12) Patent Application Publication
(10) Pub. No.: US 2004/0018738 A1
(43) Pub. Date: Jan. 29, 2004

(54) Method for fabricating a notch gate structure of a field effect transistor

(76) Inventor: Wei Liu, San Jose, CA (US)

Correspondence Address: Patent Counsel, Applied Materials, Inc., P.O. Box 450A, Santa Clara, CA, 95052, US

(21) Appl. No.: 10/624,763

(22) Filed: Jul. 21, 2003

Related U.S. Application Data
(60) Provisional application No. 60/398,042, filed on Jul. 22, 2002.

(51) Int. Cl. H01L 21/311

(52) U.S. Cl. 438/700; 438/701; 438/702; 438/703

(57) ABSTRACT

A method for fabricating features on a substrate having reduced dimensions is provided. The features are formed by defining a first mask through one or more layers of a multilayer stack formed on a substrate. The first mask is defined using lithographic techniques. A second mask is then conformably formed on one or more sidewalls of the first mask. Using the second mask as an etch mask, the remaining layers of the multilayer stack are etched to the substrate surface forming an opening in the multilayer stack. The features are completed by filling the opening with one or more material layers followed by removal of the multilayer stack.

### CROSS-REFERENCE TO RELATED APPLICATIONS

This application claims benefit of U.S. provisional application Serial No. 60/398,042, filed Jul. 22, 2002, which is herein incorporated by reference.

### BACKGROUND OF THE INVENTION

1. Field of the Invention

The present invention generally relates to a method for fabricating devices on semiconductor substrates. More specifically, the present invention relates to a method for fabricating a gate structure of a field effect transistor.

2. Description of the Background Art

Ultra-large-scale integrated (ULSI) circuits typically include more than one million transistors that are formed on a semiconductor substrate and cooperate to perform various functions within an electronic device. Such transistors may include complementary metal-oxide-semiconductor (CMOS) field effect transistors.

A CMOS transistor includes a gate structure that is disposed between a source region and a drain region defined in the semiconductor substrate. The gate structure generally comprises a gate electrode formed on a gate dielectric material. The gate electrode controls a flow of charge carriers, beneath the gate dielectric, in a channel region that is formed between the drain and source regions, so as to turn the transistor on or off. The channel, drain and source regions are collectively referred to in the art as a “transistor junction”. There is a constant trend to reduce the dimensions of the transistor junction and, as such, decrease the gate electrode width in order to facilitate an increase in the operational speed of such transistors.

In a CMOS transistor fabrication process, a lithographically patterned mask is used during etch and deposition processes to form the gate electrode. However, as the dimensions of the transistor junction decrease (e.g., dimensions less than about 100 nm), it is difficult to accurately define the gate electrode width using conventional lithographic techniques. Additionally, after the gate electrode is formed, the width thereof is reduced using an isotropic etch process. Such isotropic etch processes are unreliable in that the undercut profile of the gate electrode is difficult to control so that gate width critical dimensions (CD) are not repeatable from wafer to wafer and production costly.

Therefore, there is a need in the art for a method of fabricating a gate structure of a field effect transistor having reduced dimensions.

### SUMMARY OF THE INVENTION

The present invention is a method for fabricating features on a substrate having reduced dimensions. The features are formed by defining a first mask through one or more layers of a multilayer stack formed on a substrate. The first mask is defined using lithographic techniques. A second mask is then conformably formed on one or more sidewalls of the first mask. Using the second mask as an etch mask, the remaining layers of the multilayer stack are etched to the substrate surface forming an opening in the multilayer stack. The second mask is then removed to create a T-shaped opening in the multilayer stack. The features are completed by filling the T-shaped opening with one or more material layers followed by removal of the multilayer stack.

In one embodiment of the present invention a notch gate structure of a field effect transistor is fabricated. The notch gate structure comprises a gate electrode formed on a gate dielectric layer. The notch gate structure is fabricated by depositing a multilayer stack on a gate dielectric layer over a plurality of regions wherein transistor junctions are to be defined on the substrate. A first mask is lithographically defined through one or more layers of the multilayer stack. A second mask is then conformably formed on one or more sidewalls of the first mask to define the width of the notch gate. Thereafter, using the second mask as an etch mask, the remaining layers of the multilayer stack are etched to the gate dielectric layer followed by removal of the second mask, forming a notch gate opening in the multilayer stack. The notch gate structure is completed by filling the notch gate opening with polysilicon (poly-Si) followed by removal of the multilayer stack.

### BRIEF DESCRIPTION OF THE DRAWINGS

The teachings of the present invention can be readily understood by considering the following detailed description in conjunction with the accompanying drawings, in which:

FIGS. 1A and 1B depict a flow diagram of a method for fabricating a notch gate structure of a field effect transistor in accordance with the present invention;

FIGS. 2A-2L depict schematic, cross-sectional views of a substrate having a notch gate structure being formed in accordance with the method of FIGS. 1A-1B; and

FIG. 3 depicts a schematic diagram of an exemplary plasma processing apparatus of the kind used in performing portions of the inventive method.

To facilitate understanding, identical reference numerals have been used, where possible, to designate identical elements that are common to the figures.

It is to be noted, however, that the appended drawings illustrate only exemplary embodiments of this invention and are therefore not to be considered limiting of its scope, for the invention may admit to other equally effective embodiments.

### DETAILED DESCRIPTION

The present invention is a method for fabricating features on a substrate having reduced dimensions. The features are formed by defining a first mask through one or more layers of a multilayer stack formed on a substrate. The first mask is defined using lithographic techniques. A second mask is then conformably formed on one or more sidewalls of the first mask. Using the second mask as an etch mask, the remaining layers of the multilayer stack are etched to the substrate surface forming an opening in the multilayer stack. The second mask is then removed to create a T-shaped opening in the multilayer stack. The features are completed by filling the opening with one or more material layers followed by removal of the multilayer stack.

The present invention is illustratively described with reference to a method for fabricating a notch gate structure of a field effect transistor on a substrate. The notch gate structure comprises a notch gate electrode formed on a gate dielectric layer.

The notch gate structure is fabricated by depositing a multilayer stack on a gate dielectric layer over a plurality of regions wherein transistor junctions are to be defined on the substrate. A first mask is lithographically defined through one or more layers of the multilayer stack. A second mask is then conformably formed on one or more sidewalls of the first mask to define the width of the notch gate electrode. Thereafter, using the second mask as an etch mask, the remaining layers of the multilayer stack are etched to the gate dielectric layer, forming a notch gate opening in the multilayer stack followed by removal of the second mask. The notch gate structure is completed by filling the notch gate opening with polysilicon (poly-Si) followed by removal of the multilayer stack.

The thickness of the second mask conformably formed on one or more sidewalls of the first mask determines the width for the notch gate electrodes of the transistors. The thickness of the multilayer stack defines the height of the notch. Therefore, both the width and the height of the notch and can be accurately determined because such thicknesses depend on deposition processes rather than on lithography processes. As such, notch gate structures having notch widths less than 30 nm may be formed.

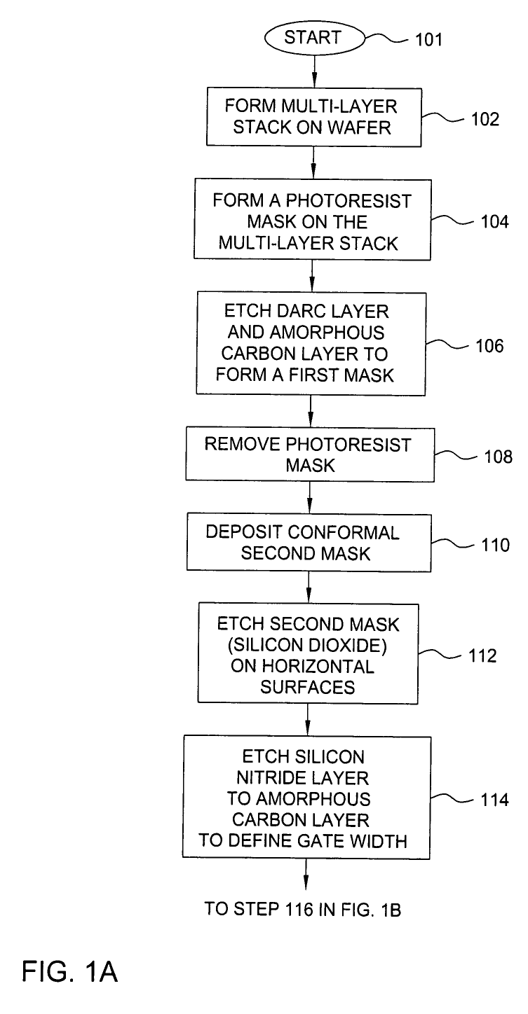

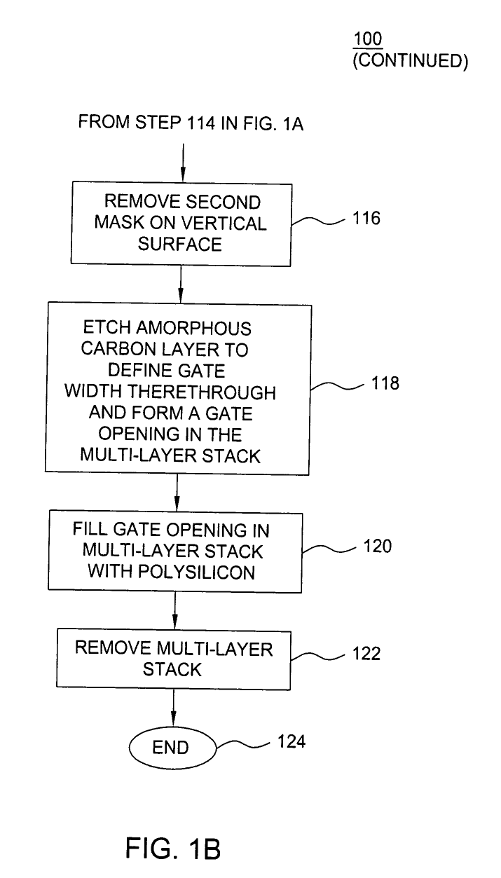

FIGS. 1A-1B together depict a flow diagram of a process sequence 100 for fabricating a notch gate electrode in accordance with the present invention. The sequence 100 comprises process steps that are performed upon a multilayer stack during fabrication of a notch gate structure of a field effect transistor (e.g., CMOS transistor).

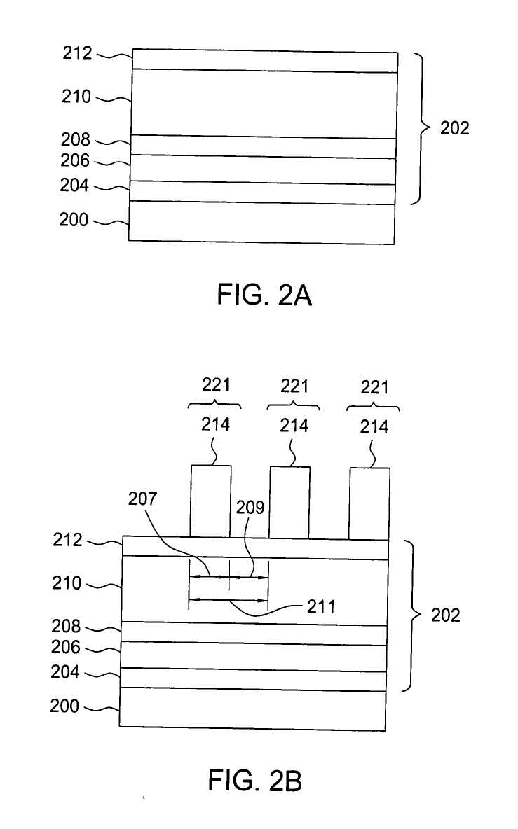

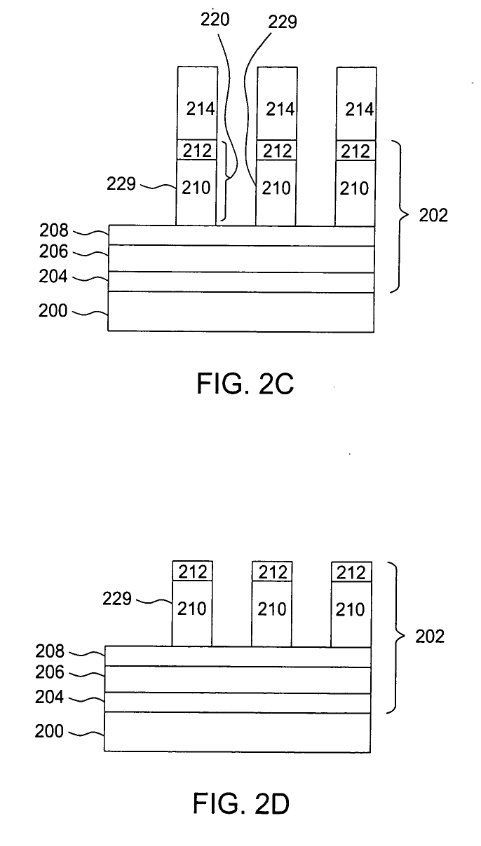

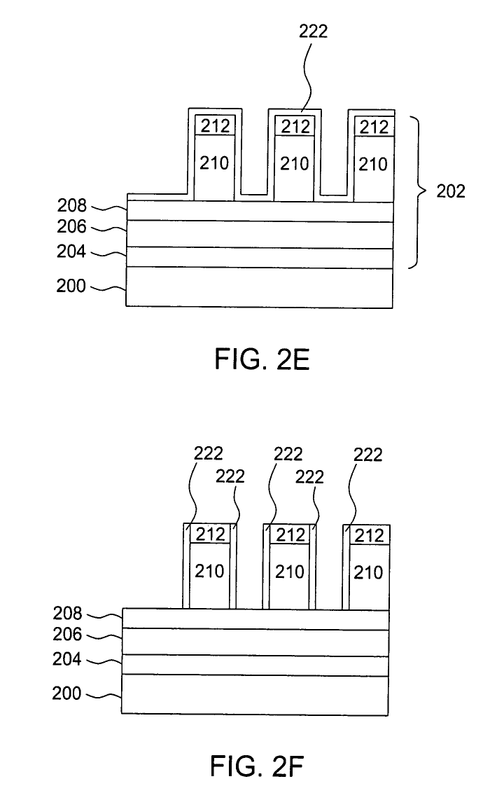

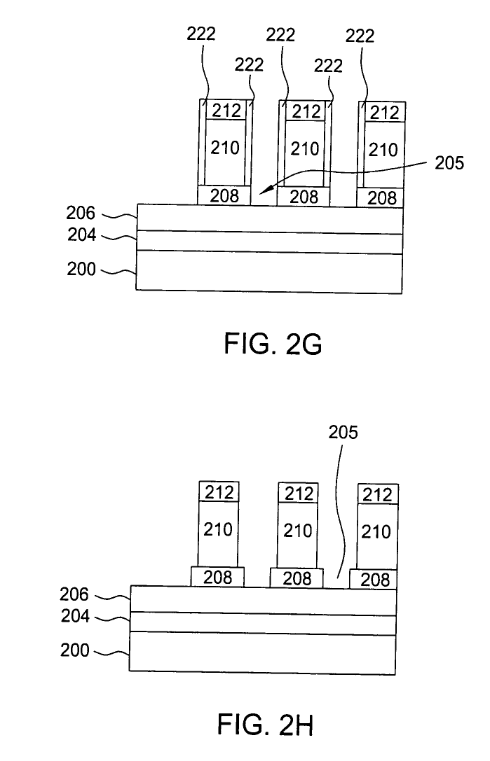

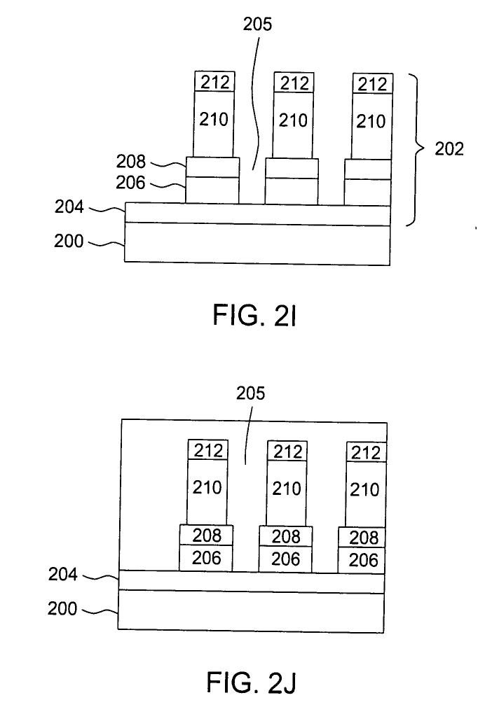

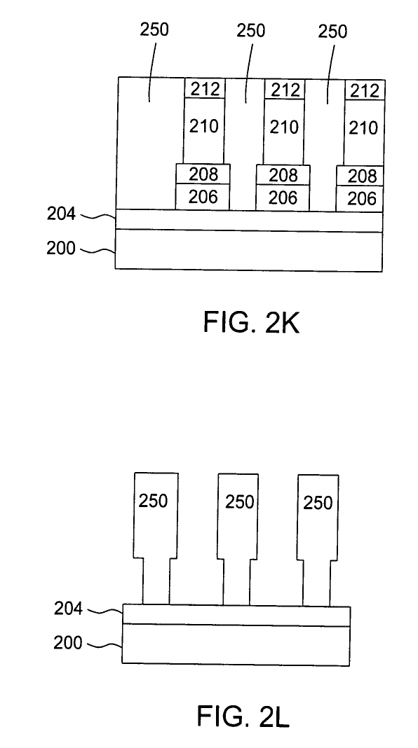

FIGS. 2A-2L depict a sequence of schematic cross-sectional views of a substrate showing a notch gate electrode being formed thereon using process sequence 100 of FIG. 1. To best understand the invention, the reader should simultaneously refer to FIGS. 1A-1B and FIGS. 2A-2L. The views in FIGS. 2A-2L relate to individual processing steps that are used to form the notch gate electrode. Sub-processes and lithographic routines (e.g., exposure and development of photoresist, wafer cleaning procedures, and the like) are not shown in FIGS. 1A-1B and FIGS. 2A-2L. The images in FIGS. 2A-2L are not depicted to scale and are simplified for illustrative purposes.

Process sequence 100 begins at step 101 and proceeds to step 102 where a multilayer stack 202 is formed on a wafer 200 (FIG. 2A). The wafer 200, e.g., is a silicon (Si) wafer having a dielectric layer 204 formed thereon. The multilayer stack 202 may include, for example, a layer of amorphous carbon (α-carbon) (layer 206) to a thickness of about 250-400 Angstroms, a layer of silicon nitride (Si₃N₄) (layer 208) to a thickness of 50-150 Angstroms, a layer of amorphous carbon (α-carbon) (layer 210) to a thickness of 1000-1500 Angstroms and a dielectric anti-reflective coating (DARC) (layer 212) to a thickness of 100-300 Angstroms. The dielectric anti-reflective coating (DARC) (layer 212) may comprise silicon oxynitride (SiON), and the like. The dielectric layer 204 is formed, for example, of an oxide such as, for example, silicon dioxide (SiO₂) to a thickness of about 15 to 60 Angstroms. It should be understood, however, that the multilayer stack 202 may comprise layers formed from other materials or layers having different thicknesses.

The layers that comprise the multilayer stack 202 may be deposited using any vacuum deposition technique such as atomic layer deposition (ALD), physical vapor deposition (PVD), chemical vapor deposition (CVD), evaporation, and the like. Fabrication of the CMOS field effect transistors may be performed using the respective processing modules of CENTURA®, ENDURA®, and other semiconductor wafer processing systems available from Applied Materials, Inc. of Santa Clara, Calif.

The DARC layer 212 functions to minimize the reflection of light during patterning steps. As feature sizes are reduced, inaccuracies in etch mask pattern transfer processes can arise from optical limitations that are inherent to the lithographic process, such as, for example, light reflection. DARC layer 212 deposition techniques are described in commonly assigned U.S. patent application Ser. Nos. 09/590,322, filed Jun. 8, 2000 (Attorney Docket No. 4227) and 09/905,172 filed Jul. 13, 2001 (Attorney Docket No. 4227-02), which are herein incorporated by reference.

At step 104, a photoresist mask 214 is formed on the DARC layer 212. The photoresist mask 214 is formed using a conventional lithographic patterning routine, i.e., photoresist is exposed through a mask, developed, and the undeveloped portion of the photoresist is removed. The developed photoresist is generally a carbon-based polymer that remains as an etch mask on top of the DARC layer 212 in the regions 221 that are intended to be protected during an etch process (FIG. 2B). The photoresist mask 214 has a line width 207 (e.g., about 100 nm) and a space 209 (e.g., about 100 nm) which together define the pitch 211 (i.e., line width plus space, 100 nm+100 nm=200 nm).

At step 106, the pattern of the photoresist mask 214 is transferred through the DARC layer 212 and the amorphous carbon layer 210 (FIG. 2C) to form a first mask 220. During step 106 the DARC layer 212 is etched using a fluorocarbon gas (e.g., carbon tetrafluoride (CF₄), sulfur hexafluoride (SF₆), trifluoromethane (CHF₃), difluoromethane (CH₂F₂), and the like). Thereafter, the amorphous carbon layer 210 is etched using an etch process that includes a gas (or gas mixture) comprising hydrogen bromide (HBr), oxygen (O₂), and at least one inert gas, such as, for example, argon (Ar), helium (He), neon (Ne), and the like. Herein the terms “gas” and “gas mixture” are used interchangeably. In one embodiment, step 106 uses the photoresist mask 214 as an etch mask and the silicon nitride (Si₃N₄) layer 208 as an etch stop layer. Alternatively, an endpoint detection system of the etch reactor may monitor plasma emissions at a particular wavelength to determine an end of the etch process. Further, both etch processes of step 106 may be performed in-situ (i.e., in the same etch reactor).

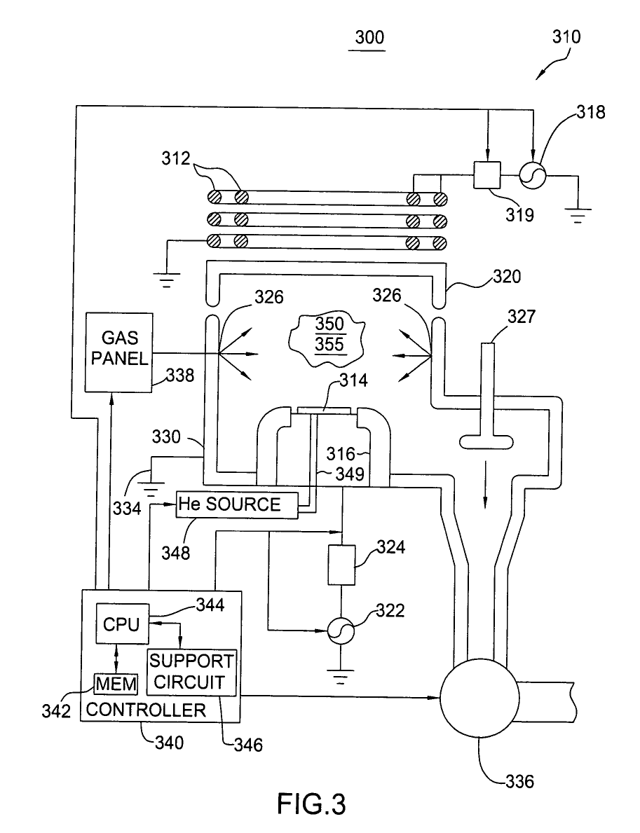

Step 106 may be performed in an etch reactor such as a Decoupled Plasma Source (DPS) II module of the CENTURA® system available from Applied Materials, Inc. of Santa Clara, Calif. The DPS II module uses a 2 MHz inductive plasma source to produce a high-density plasma. The wafer is biased by a 13.56 MHz bias source. The decoupled nature of the plasma source allows independent control of ion energy and ion density. The DPS II module is described below in more detail with reference to FIG. 3.

In one illustrative embodiment, the DARC layer 212 comprising silicon oxynitride (SiON) is etched using carbon tetrafluoride (CF₄) at a flow rate of 40 to 200 sccm, argon (Ar) at a flow rate of 40 to 200 sccm (i.e., a CF₄:Ar flow ratio of 1:5 to 5:1), plasma power of 250 W to 750 W, bias power of 0 to 300 W, and maintaining the wafer pedestal at a temperature between 40 and 85 degrees Celsius at a chamber pressure of 2 to 10 mTorr. The DARC layer 212 etch process is terminated by observing the magnitude of the plasma emission spectrum at 3865 Angstroms, which will drop significantly after the underlying amorphous carbon layer 210 is reached, and subsequently conducting a 40% over etch (i.e., continuing the etch process for 40% of the time that led up to the observed change in the magnitude of the emission spectra).

One exemplary silicon oxynitride (SiON) DARC layer 212 etch process is performed using carbon tetrafluoride (CF₄) at a flow rate of 120 sccm, argon (Ar) at a flow rate of 120 sccm (i.e., a CF₄:Ar flow ratio of about 1:1), a plasma power of 360 W, a bias power of 60 W, a wafer pedestal temperature of about 65 degrees Celsius and a chamber pressure of 4 mTorr.

In one illustrative embodiment, the amorphous carbon layer 210 is etched using hydrogen bromide (HBr) at a flow rate of 20 to 100 sccm, oxygen (O₂) at a flow rate of 5 to 60 sccm (i.e., a HBr:O₂ flow ratio of 1:3 to 20:1) argon (Ar) at a flow rate of 20 to 100 sccm, plasma power of 200 W to 1500 W, bias power of 0 to 300 W, and maintaining the wafer pedestal at a temperature between 40 and 85 degrees Celsius at a chamber pressure of 2 to 10 mTorr. The amorphous carbon layer 210 etch process is terminated by observing the magnitude of the plasma emission spectrum at 4835 Angstroms, which will drop significantly after the underlying silicon nitride layer 208 is reached, and subsequently conducting a 30% over etch to remove residues (i.e., continuing the etch process for 30% of the time that led up to the observed change in the magnitude of the emission spectra).

One exemplary amorphous carbon layer 210 etch process is performed using hydrogen bromide (HBr) at a flow rate of 60 sccm, oxygen (O₂) at a flow rate of 20 sccm (i.e., a HBr:O₂ flow ratio of about 3:1), Ar at a flow rate of 60 sccm, a plasma power of 600 W, a bias power of 100 W, a wafer pedestal temperature of 65 degrees Celsius, and a pressure of 4 mTorr. Such process has etch directionality of at least 20:1. Herein the term “etch directionality” is used to describe a ratio of the etch rates at which the carbon layer 210 is removed on horizontal surfaces and on vertical surfaces, such as sidewalls 229. During step 106, the high etch directionality of the etch process protects the sidewalls 229 of the photoresist mask 214 and amorphous carbon layer 210 from lateral etching and, as such, preserves the dimensions thereof.

At step 108, the photoresist mask 214 is removed (or stripped) from the substrate (FIG. 2D). Generally, step 108 is performed using a conventional photoresist stripping process that uses an oxygen-based chemistry, e.g., a gas mixture comprising oxygen and nitrogen. Alternatively, step 108 may use the same gases used for etching the amorphous carbon layer 210 in step 106, as well as be performed in the same etch reactor. During step 108, as with step 106, the etching chemistry and process parameters are specifically selected to provide high etch directionality to preserve the dimensions and location of the amorphous carbon layer 210. In one illustrative embodiment, steps 106 and 108 are performed in-situ using, e.g., the DPS II module.

One exemplary photoresist stripping process is performed using hydrogen bromide (HBr) at a flow rate of 60 sccm, oxygen (O₂) at a flow rate of 20 sccm (i.e., a HBr:O₂ flow ratio of about 3:1), argon (Ar) at a flow rate of 60 sccm, a plasma power of 600 W, a bias power of 100 W, a wafer pedestal temperature of 65 degrees Celsius, and a chamber pressure of 4 mTorr. Such stripping process has etch directionality of at least 10:1, as well as etch selectivity of the DARC film 212 (e.g., silicon oxynitride (SiON)) over photoresist (mask 214) of at least 1:20.

At step 110, a second mask 222 is conformably deposited onto the wafer 200 (FIG. 2E) using a conventional deposition technique, such as atomic layer deposition (ALD), physical vapor deposition (PVD), chemical vapor deposition (CVD) plasma enhanced CVD (PECVD), and the like. The second mask 222 is deposited to a sidewall thickness 231 sufficient to define the gate electrode width. The second mask 222 is generally formed from a material that is etched with the same etchants that are used to etch the underlying silicon nitride (Si₃N₃) layer 208. An example of such a material is silicon dioxide (SiO₂), and the like.

At step 112, the second mask 222 is etched and removed from the horizontal surfaces (i.e., surface of the silicon nitride (Si₃N₄) layer 206 and top surface of the DARC layer 212) (FIG. 2F). During step 112, some of the DARC layer 212 may also be removed.

In one embodiment, the second mask 222 (e.g., silicon dioxide (SiO₂)) is etched from the horizontal surfaces using a gas mixture comprising carbon tetrafluoride (CF₄), and an inert gas, such as argon (Ar), helium (He), neon (Ne), and the like. Such etch process can be performed using the DPS II module by providing carbon tetrafluoride (CF₄) at a flow rate of 40 to 200 sccm, argon (Ar) at a flow rate of 40 to 200 sccm, plasma power of 250 W to 750 W, bias power of 0 to 300 W, and maintaining the wafer pedestal at a temperature between 40 and 85 degrees Celsius at a chamber pressure of 2 to 10 mTorr. The second mask 222 etch process is terminated by observing the magnitude of the plasma emission spectrum at 3865 Angstroms, which will increase after the underlying silicon nitride layer 208 is reached, and subsequently conducting up to a 40% over etch (i.e., continuing the etch process for up to 40% of the time that led up to the observed change in the magnitude of the emission spectra).

One exemplary second mask 222 etch process is performed using carbon tetrafluoride (CF₄) at a flow rate of 120 sccm, argon (Ar) at a flow rate of 120 sccm, a plasma power of 360 W, a bias power of 60 W, a wafer pedestal temperature of about 65 degrees Celsius and a chamber pressure of 4 mTorr.

At step 114, the silicon nitride layer 208 is etched to define the gate electrode width 205 therethrough (FIG. 2G). In one embodiment, the silicon nitride layer 208 is etched using a gas mixture comprising carbon tetrafluoride (CF₄), and an inert gas, such as argon (Ar), helium (He), neon (Ne), and the like. Such etch process can be performed using the DPS II module by providing carbon tetrafluoride (CF₄) at a flow rate of 40 to 200 sccm, argon (Ar) at a flow rate of 40 to 200 sccm, plasma power of 250 W to 750 W, bias power of 0 to 300 W, and maintaining the wafer pedestal at a temperature between 40 and 85 degrees Celsius at a chamber pressure of 2 to 10 mTorr. The silicon nitride layer 208 etch process is terminated by observing the magnitude of the plasma emission spectrum at 3865 Angstroms, which will drop significantly after the underlying amorphous carbon layer 206 is reached, and subsequently conducting up to a 40% over etch (i.e., continuing the etch process for up to 40% of the time that led up to the observed change in the magnitude of the emission spectra).

One exemplary silicon nitride layer 208 etch process is performed using carbon tetrafluoride (CF₄) at a flow rate of 120 sccm, argon (Ar) at a flow rate of 120 sccm, a plasma power of 360 W, a bias power of 60 W, a wafer pedestal temperature of about 65 degrees Celsius and a chamber pressure of 4 mTorr. Steps 112 and 114 may optionally be performed sequentially as one step in the same etch reactor.

At step 116, the second mask 222 is removed (FIG. 2H). In one illustrative embodiment, the second mask 222 comprising silicon dioxide (SiO₂) is selectively etched using a buffered oxide etch (BOE) that simultaneously removes the second mask as well as by-products of the etch process of steps 112 and 114. In one embodiment, the BOE process exposes the wafer 200 to a solution comprising hydrogen fluoride (HF), ammonium fluoride (NH₄F), and deionized water. After the exposure, the wafer 220 is rinsed in distilled water to remove any remaining traces of the BOE etchant. In one exemplary embodiment, the solution comprises, by volume NH₄F and HF in a ratio of about 6:1, at a temperature of about 10 to 30 degrees Celsius. The BOE process can be performed using e.g., an automated wet cleaning module that is described in commonly assigned U.S. patent application Ser. No. 09/945,454, filed Aug. 31, 2001 (Attorney Docket No. 4936), which is herein incorporated by reference. Such wet cleaning module is available from Applied Materials, Inc. of Santa Clara, Calif. The BOE etch process has an etch selectivity for the second mask 222 (silicon dioxide (SiO₂)) over silicon nitride (Si₃N₄) (layer 208) of at least 5:1.

At step 118, the amorphous carbon layer 206 is etched to transfer the gate width 205 therethrough (FIG. 2I) to the gate dielectric layer 204 forming notch gate electrode openings in the multilayer stack 202. In one embodiment, step 118 may use the amorphous carbon etching process described above with reference to step 106.

At step 120, the notch gate electrode openings are filled with doped or undoped polysilicon to form notch gate electrodes 250 (FIG. 2J). The polysilicon notch gate electrodes 250 may be deposited using any vacuum deposition technique such as an atomic layer deposition (ALD), physical vapor deposition (PVD), chemical vapor deposition (CVD), evaporation, and the like. Fabrication of the CMOS field effect transistors may be performed using the respective processing modules of CENTURA®, ENDURA®, and other semiconductor wafer processing systems available from Applied Materials, Inc. of Santa Clara, Calif.

After the notch gate openings are filled with the doped polysilicon, a chemical mechanical polishing (CMP) process may be performed to remove any polysilicon that is deposited on top of the multilayer stack 202 (FIG. 2K). Chemical mechanical polishing processes may be performed using the REFLEXION® Chemical Mechanical Polishing system available from Applied Materials, Inc. of Santa Clara, Calif.

At step 122, the layers of the multilayer stack 202 are etched and removed from the substrate 200 forming the notch gate structures (FIG. 2L). In one illustrative embodiment, step 122 is performed using the etch processes described above with reference to step 106 for removing the DARC layer 212 and amorphous carbon layers 206, 210. Alternatively, steps 206 and 210 may be performed in any conventional plasma strip chamber using an oxygen-containing plasma (i.e., ASP chamber available from Applied Materials, Inc. of Santa Clara, Calif.). Thereafter, the silicon nitride layer 208 may be removed using a conventional hot phosphoric acid (H₃PO₄) etch process. In one embodiment, the wafer 200 is exposed to a phosphoric acid solution at a temperature of about 160° C. After the exposure, the wafer 200 is rinsed in distilled water to remove any remaining traces of the phosphoric acid etchant. Such phosphoric acid etchant process can be performed using, e.g., an automated wet cleaning module that is described in commonly assigned U.S. patent application Ser. No. 09/945,454, filed Aug. 31, 2001 (Attorney Docket No. 4936), which is herein incorporated by reference. Such wet cleaning module is available from Applied Materials, Inc. of Santa Clara, Calif.

At step 124, the method 100 ends.

One illustrative embodiment of an etch reactor that can be used to perform the etching step(s) of the present invention is depicted in FIG. 3.

FIG. 3 depicts a schematic diagram of the DPS II etch reactor 300 that may be used to practice the inventive method. The process chamber 310 comprises at least one inductive coil antenna segment 312, positioned exterior to a dielectric ceiling 320. Other modifications may have other types of ceilings, e.g., a dome-shaped ceiling. The antenna segment 312 is coupled to a radio-frequency (RF) source 318 that is generally capable of producing an RF signal having a tunable frequency of about 50 kHz and 13.56 MHz. The RF source 318 is coupled to the antenna 312 through a matching network 319. Process chamber 310 also includes a wafer support pedestal (cathode) 316 that is coupled to a source 322 that is generally capable of producing an RF signal having a frequency of approximately 13.56 MHz. The source 322 is coupled to the cathode 316 through a matching network 324. Optionally, the source 322 may be a DC or pulsed DC source. The chamber 310 also contains a conductive chamber wall 330 that is connected to an electrical ground 334. A controller 340 comprising a central processing unit (CPU) 344, a memory 342, and support circuits 346 for the CPU 344 is coupled to the various components of the DPS etch process chamber 310 to facilitate control of the etch process.

In operation, the semiconductor wafer 314 is placed on the wafer support pedestal 316 and gaseous components are supplied from a gas panel 338 to the process chamber 310 through entry ports 326 to form a gaseous mixture 350. The gaseous mixture 350 is ignited into a plasma 355 in the process chamber 310 by applying RF power from the RF sources 318 and 322 respectively to the antenna 312 and the cathode 316. The pressure within the interior of the etch chamber 310 is controlled using a throttle valve 327 situated between the chamber 310 and a vacuum pump 336. The temperature at the surface of the chamber walls 330 is controlled using liquid-containing conduits (not shown) that are located in the walls 330 of the chamber 310.

The temperature of the wafer 314 is controlled by stabilizing the temperature of the support pedestal 316 by flowing helium gas from source 348 to channels formed by the back of the wafer 314 and grooves (not shown) on the pedestal surface. The helium gas is used to facilitate heat transfer between the pedestal 316 and the wafer 314. During the processing, the wafer 314 is heated by a resistive heater within the pedestal to a steady state temperature and the helium facilitates uniform heating of the wafer 314. Using thermal control of both the ceiling 320 and the pedestal 316, the wafer 314 is maintained at a temperature of between 0 and 500 degrees Celsius. The RF power applied to the inductive coil antenna 312 has a frequency between 50 kHz and 13.56 MHz and has a power of 200 to 3000 Watts. The bias power of between 0 and 300 Watts is applied to the pedestal 316 and may be in a form of a DC, pulsed DC, or RF power.

To facilitate control of the chamber as described above, the CPU 344 may be one of any form of general purpose computer processor that can be used in an industrial setting for controlling various chambers and sub-processors. The memory 342 is coupled to the CPU 344. The memory 342, or computer-readable medium, may be one or more of readily available memory such as random access memory (RAM), read only memory (ROM), floppy disk, hard disk, or any other form of digital storage, local or remote. The support circuits 346 are coupled to the CPU 344 for supporting the processor in a conventional manner. These circuits include cache, power supplies, clock circuits, input/output circuitry and subsystems, and the like. The inventive method is generally stored in the memory 342 as software routine. The software routine may also be stored and/or executed by a second CPU (not shown) that is remotely located from the hardware being controlled by the CPU 344.

The invention may be practiced using other semiconductor wafer processing systems wherein the processing parameters may be adjusted to achieve acceptable characteristics by those skilled in the arts by utilizing the teachings disclosed herein without departing from the spirit of the invention.

Although the forgoing discussion referred to fabrication of the field effect transistor, fabrication of the other devices and structures used in the integrated circuits can benefit from the invention.

While foregoing is directed to the illustrative embodiment of the present invention, other and further embodiments of the invention may be devised without departing from the basic scope thereof, and the scope thereof is determined by the claims that follow.

What is claimed is:

1. A method of defining a feature on a substrate, comprising:
(a) providing a substrate having a multilayer stack formed thereon;
(b) forming a first mask through one or more layers of the multilayer stack;
(c) forming a second mask on one or more sidewalls of the first mask;
(d) etching one or more layers of the multilayer stack to the substrate surface using the second mask to form an opening in the multilayer stack;
(e) filling the opening formed in the multilayer stack with one or more material layers; and
(f) removing the multilayer stack from the substrate leaving thereon a feature formed of the one or more material layers.

2. The method of claim 1 wherein step (b) further comprises:
(b1) forming a photoresist pattern on the multilayer stack;
(b2) transferring the photoresist pattern through one or more layers of the multilayer stack; and
(b3) removing the photoresist pattern from the multilayer stack.

3. The method of claim 1 wherein the first mask comprises at least one of a dielectric antireflective coating (DARC) and an amorphous carbon layer.

4. The method of claim 1 wherein step (c) further comprises;
(c1) depositing a second mask layer conformably on the first mask; and
(c2) etching portions of the second mask layer on horizontal surfaces of the substrate leaving the second mask layer on one or more sidewalls of the first mask.

5. The method of claim 1 wherein the second mask comprises a material selected from the group consisting of silicon dioxide (SiO₂) and silicon nitride (Si₃N₄).

6. The method of claim 1 wherein the one or more material layers filling the opening formed in the multilayer stack comprise polysilicon.

7. A method of fabricating a notch gate structure of a field effect transistor comprising:
(a) providing a substrate having a multilayer stack formed on a gate dielectric layer;
(b) forming a first mask through one or more layers of the multilayer stack;
(c) forming a second mask on one or more sidewalls of the first mask;
(d) etching one or more layers of the multilayer stack to the surface of the gate dielectric layer using the second mask to form a notch gate opening in the multilayer stack;
(e) filling the notch gate opening formed in the multilayer stack with one or more material layers; and
(f) removing the multilayer stack from the substrate leaving thereon a a notch gate electrode formed on the gate dielectric layer.

8. The method of claim 7 wherein step (b) further comprises:
(b1) forming a photoresist pattern on the multilayer stack;
(b2) transferring the photoresist pattern through one or more layers of the multilayer stack; and
(b3) removing the photoresist pattern from the multilayer stack.

9. The method of claim 7 wherein the first mask comprises at least one of a dielectric antireflective coating (DARC) and an amorphous carbon layer.

10. The method of claim 7 wherein step (c) further comprises:
(c1) depositing a second mask layer conformably on the first mask; and
(c2) etching portions of the second mask layer on horizontal surfaces of the substrate leaving the second mask layer on one or more sidewalls of the first mask.

11. The method of claim 7 wherein the second mask comprises a material selected from the group consisting of silicon dioxide (SiO₂) and silicon nitride (Si₃N₄).

12. The method of claim 7 wherein the one or more material layers filling the notch gate opening formed in the multilayer stack comprise polysilicon.

13. A method of fabricating a field effect transistor, comprising:
(a) providing a substrate having a multilayer stack formed on a gate dielectric layer;
(b) forming a first mask through one or more layers of the multilayer stack;
(c) forming a second mask on one or more sidewalls of the first mask;
(d) etching one or more layers of the multilayer stack to the surface of the gate dielectric layer using the second mask to form a notch gate opening in the multilayer stack;
(e) filling the notch gate opening formed in the multilayer stack with one or more material layers; and
(f) removing the multilayer stack from the substrate leaving thereon a a notch gate electrode formed on the gate dielectric layer.

14. The method of claim 13 wherein step (b) further comprises:
(b1) forming a photoresist pattern on the multilayer stack;
(b2) transferring the photoresist pattern through one or more layers of the multilayer stack; and
(b3) removing the photoresist pattern from the multilayer stack.

15. The method of claim 13 wherein the first mask comprises at least one of a dielectric antireflective coating (DARC) and an amorphous carbon layer.

16. The method of claim 13 wherein step (c) further comprises:
(c1) depositing a second mask layer conformably on the first mask; and
(c2) etching portions of the second mask layer on horizontal surfaces of the substrate leaving the second mask layer on one or more sidewalls of the first mask.

17. The method of claim 13 wherein the second mask comprises a material selected from the group consisting of silicon dioxide (SiO₂) and silicon nitride (Si₃N₄).

18. The method of claim 13 wherein the one or more material layers filling the notch gate opening formed in the multilayer stack comprise polysilicon.
